(19) United States
(12) Patent Application Publication
(10) Pub. No.: US 2020/0191842 A1
(43) Pub. Date: Jun. 18, 2020

(54) Device and Process for Detecting Electrical Meter Motion

(71) Applicant: PECO Energy Company, Philadelphia, PA (US)

(72) Inventors: Jason Zola, LaGrange Park, IL (US); Bryan N. Uber, Glassboro, NJ (US)

(21) Appl. No.: 16/223,871

(22) Filed: Dec. 18, 2018

(51) Int. Cl. G01R 22/06; G01R 11/24

(52) U.S. Cl. CPC G01R 22/066; G01R 22/063; G01D 4/002; G01R 11/24; G01R 22/065

(57) ABSTRACT

A device and process for detecting electrical meter tampering and for remotely monitoring the device status which includes a motion sensor, a computer, and a transceiver. The motion sensor is adapted to generate a signal indicative of the device motion. The computer is configured to receive signals indicated of the device motion. The transceiver it is in signal communication with the computer and adapted to transmit a signal indicative of the status of the device and receive instructions as to the device operation.

### FIELD OF THE INVENTION

This invention relates to a device for detecting electrical tampering and a method for remotely monitoring the device status.

### BACKGROUND

Electrical meters record the amount of energy delivered from electricity providers by measuring the electricity flow. Electrical meter tampering is characterized by activities such as bypassing the electrical meter, diverting electrical service by physically altering the meter, attaching objects to the meter, inserting objects into the meter, and other electrical or mechanical means of tampering with, bypassing, or diverting the flow of electricity. Electrical meter tampering may result in improper electrical connections which may cause a fire at the meter and even inside the house or building to which it is attached. Public exposure, due to improperly sealed meters, is also a major safety concern, especially for children. Electrical meter tampering hampers the meter's ability to measure electricity flow, complicit in electricity theft. Electricity theft costs utilities worldwide billions of dollars in lost revenue. Passive theft prevention hardware such as meter locks are ineffective and easily defeated. There is clearly an opportunity to monitor electrical meters to detect tampering and to prevent electricity theft, property damage and potential injuries. By using a device to monitor the motion of the meter and transmit a signal indicative of meter motion to the utility or service organization, when the meter motion indicates tampering, the meter can be inspected and serviced thereby preventing the theft of electricity, preventing property damage or injuries.

### SUMMARY

This invention concerns a device for detecting electrical meter tampering. In an example embodiment, the device for detecting electrical meter tampering comprises a motion sensor, a computer in signal communication with the sensor, and a transceiver in signal communication with the computer. The motion sensor is adapted to generate a signal indicative of motion of the device. The computer is configured to receive the signals indicative of motion of the device. The transceiver is adapted to transmit a signal indicative of the status of the device and receive instructions as to device operation.

An example embodiment may further comprise a battery. In this example the battery supplies power to the device.

An example embodiment may further comprise a voltage sensor in signal communication with the computer. As an example the voltage sensor measures the voltage of the battery. In an example the computer is further configured to receive a signal indicate of the voltage.

By way of example, an embodiment may further comprise a temperature sensor. The temperature sensor is in signal communication with the computer. The temperature sensor measures a temperature of the device. As an example, the computer is further configured to receive a signal indicative of the temperature.

In an example the motion sensor of the device is an accelerometer. In another example the motion sensor is a switch.

By way of example, an embodiment may further comprise a housing. The housing is mountable on the electrical meter, enclosing and supporting the motion sensor, the computer and the transceiver. As an example the housing may be mountable on the electrical meter via an adhesive bond. As an example a Quick Response Code is attached to the housing. The Quick Response code contains a device specific identification. As an example the device specific identification is a serial number.

In an example the device may further comprise a light in signal communication with the computer. As an example the light is mounted within the housing and visible external to the housing. As an example the light is a light emitting diode.

In an example embodiment, device further comprises an antenna in signal communication with the transceiver. As an example the transceiver in cooperation with the antenna is adaptable for signal communication with a cellular network. In another example the transceiver in corporation with the antenna is adaptable for local wireless signal communication with an electronic device. As an example the electronic device is a cellular phone.

This invention also concerns in combination an electrical meter and a device for detecting motion. As an example the device for detecting motion comprises a motion sensor, a computer in signal communication with the sensor, and a transceiver in signal communication with the computer. The motion sensor is adapted to generate a signal indicative of motion of the device. The computer is configured to receive the signals indicative of motion of the device. The transceiver is adapted to transmit a signal indicative of the status of the device and receive instructions as to device operation.

An example the embodiment may further comprise a battery. In this example the battery supplies power to the device.

An example embodiment may also further comprise a voltage sensor in signal communication with the computer. As an example the voltage sensor measures the voltage of the battery. In an example the computer is further configured to receive a signal indicate of the voltage.

By way of example, the embodiment may further comprise a temperature sensor. The temperature sensor is in signal communication with the computer. The temperature sensor measures a temperature of the device. As an example, the computer is further configured to receive a signal indicative of the temperature.

In an example the motion sensor of the device is an accelerometer. In another example the motion sensor is a switch.

By way of example, the embodiment may further comprise a housing. The housing is mountable on the electrical meter, enclosing and supporting the motion sensor, the computer and the transceiver. As an example the housing may be mountable on the electrical meter via an adhesive bond. As an example a Quick Response Code is attached to the housing. The Quick Response code may contain a device specific identification. As an example the device specific identification is a serial number.

In an example the device may further comprise a light in signal communication with the computer. As an example the light is mounted within the housing and visible external to the housing. As an example the light is a light emitting diode.

In an example embodiment, the device further comprises an antenna in signal communication with the transceiver. As an example the transceiver in cooperation with the antenna is adaptable for signal communication with a cellular network. In another example the transceiver in corporation with the antenna is adaptable for local wireless signal communication with an electronic device. As an example the electronic device is a cellular phone.

The invention also concerns a process for detecting electrical meter tampering. In an example embodiment the process comprises:

detecting motion of the meter;

generating a signal indicative of the motion of the meter;

comparing the signal indicative of the motion of the meter with a threshold motion;

generating a signal indicative of tampering, when the signal indicative of the motion is greater than or equal to the threshold motion;

generating a signal indicative of no tampering, when the signal indicative of motion is less than the threshold motion; and

transmitting the signals indicative of tampering and no tampering.

As an example the embodiment further comprises measuring a temperature of the device, generating a signal indicative of the temperature of the device, and transmitting the signal indicative of the temperature. In a particular example, the embodiment further comprises measuring a voltage of a battery, generating a signal indicative of the voltage of the battery; and transmitting the signal indicative of the voltage. In an example, the embodiment further comprises receiving by a transceiver the signals indicative of tampering, of no tampering, of the device temperature, and the battery voltage.

In an example embodiment the process of detecting motion of the meter is accomplished via a switch. As an example the threshold motion is a predetermined switch state.

In an example embodiment the process of detecting motion of the meter is accomplished via an accelerometer. As an example the threshold motion is a predetermined orientation, velocity, acceleration, or shock.

In a particular embodiment the process further comprises transmitting the signals to an external server. As an example of another embodiment the process further comprises transmitting the signals to an external server via a cellular network.

In an example embodiment the process further comprises receiving instructions as to device operation

### BRIEF DESCRIPTION OF DRAWINGS

FIG. 1 is an isometric view of an example embodiment of a device for detecting electrical meter tampering;

FIG. 2 is an isometric exploded view of an example embodiment of the device, showing the enclosure, the electrical components and the meter attachment;

FIG. 3 is a schematic diagram depicting the functional organization of an example embodiment of the device;

FIG. 4 is a flow chart of an example embodiment of a process for detecting electrical meter tampering and monitoring the device operation; and

FIG. 5 is a flow chart of an example embodiment of the process for detecting electrical meter tampering and monitoring the device operation.

### DETAILED DESCRIPTION

This invention concerns a device which detects electrical meter tampering and transmits a signal indicative of tampering to a utility or service organization so that the meter can be serviced thereby preventing electricity theft, property damage or injuries.

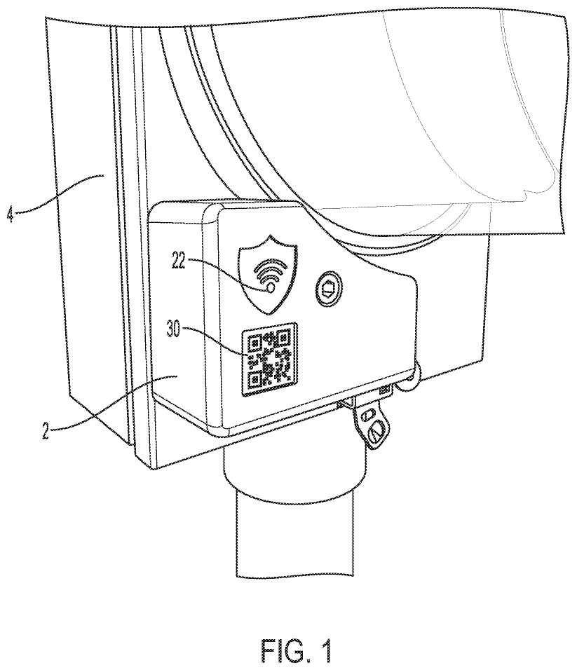

FIG. 1 illustrates an example device 2 for detecting electrical meter tampering according to this invention. The device 2 for detecting motion is used to detect tampering of electrical meter 4 on which it is mounted.

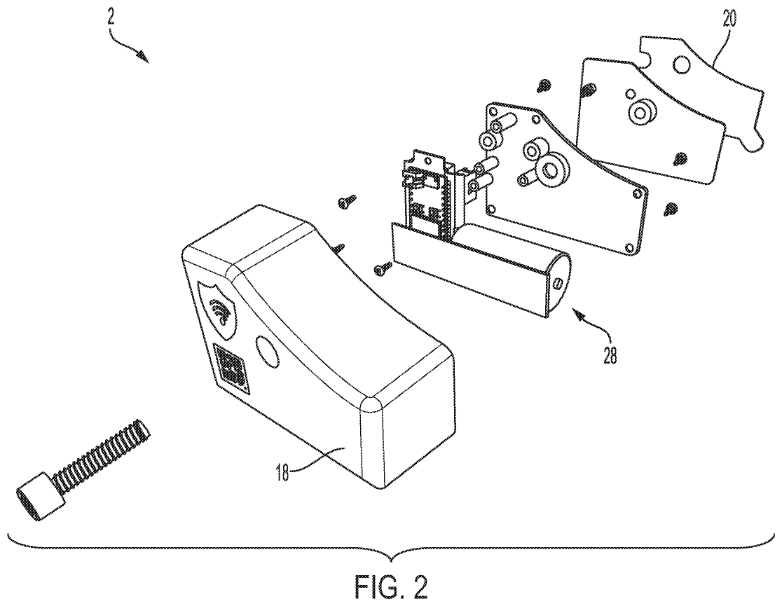

As shown in FIG. 2, device 2 further comprises a housing 18 which protects the electrical components 28 from the external environment. The housing 18 is mountable on the electrical meter 4 and encloses and supports the electrical components 28. As an example, the housing 18 is connected to the electrical meter 4 via an adhesive bond 20.

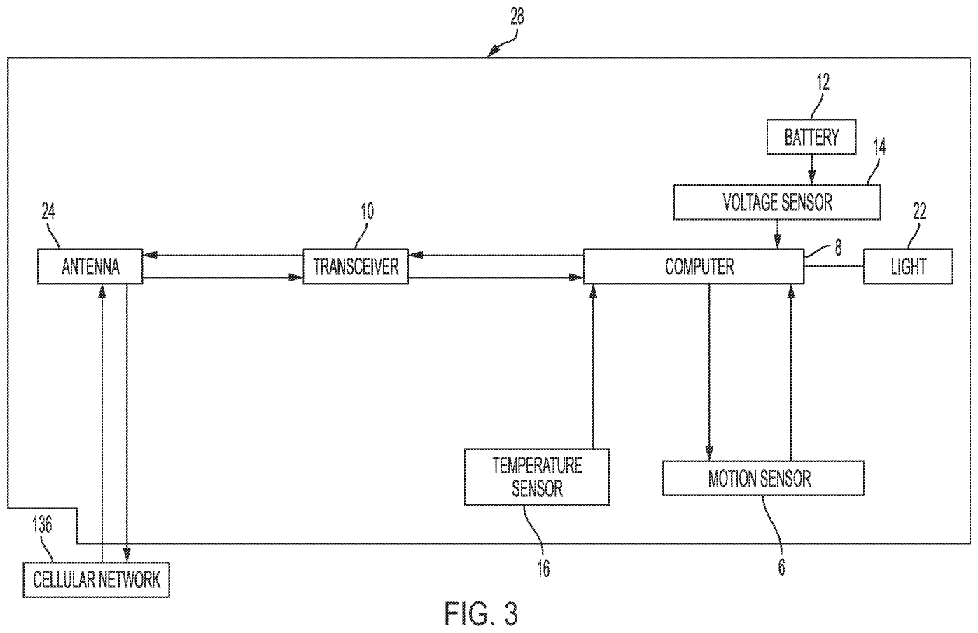

The electrical components 28 are illustrated in FIG. 3. As seen in FIG. 3, device 2 comprises a motion sensor 6 adapted to generate a signal indicative of the motion of device 2, a computer 8 in signal communication with the sensor 6, and a transceiver 10 in signal communication with the computer 8. The computer 8 is configured to receive signals indicative of motion of the device 2. The transceiver 10 is adapted to transmit a signal indicative of the status of the device 2 and to receive instructions as to operation of the device 2.

As shown in FIG. 3, the device 2 further comprises a battery 12 which supplies power to the device 2. In another example the device 2 further comprises a voltage sensor 14 in signal communication with the computer 8. The voltage sensor 14 measures the voltage of the battery 12. In this example the computer 8 is configured to receive a signal indicative of the battery voltage. In another example the device 2 further comprises a temperature sensor 16 in signal communication with the computer 8. The temperature sensor 16 measures the temperature of the device 2. In this example the computer 8 is configured to receive a signal indicative of the device temperature.

In an example embodiment, motion sensor 6 is an accelerometer. The accelerometer may measure the orientation, velocity, acceleration, or shock of device 2. In another example, motion sensor 6 is a switch. In this example, the switch may be a proximity switch.

As an example the device 2 further comprises a light 22, shown in FIGS. 1 and 3, in signal communication with the computer 8. The light 22 may be mounted within the housing 18 and visible external to the housing 18. The light 22 may be light emitting diode. The light 22 is used as an external visual indicator of tampering and the device status. For example the light may use predetermined combinations of colors and blinking patterns to indicate tampering, and whether the device is operating or needs service.

As further shown in FIG. 3, the device 2 comprises an antenna 24 in signal communication with the transceiver 10. The transceiver 10 in cooperation with the antenna 24 may be adaptable for signal communication with a cellular network 136. The transceiver 10 in cooperation with the antenna 24 may also be adaptable for local wireless signal communication with an electronic device. An example of local wireless signal communication includes using short-wavelength UHF radio waves in the IMS band from 2.4 to 2.485 GHz, such a Bluetooth™. In another example the electronic device is a cellular phone.

In practice, a technician installs the device 2 on the electrical meter 4, as shown in FIG. 1. As an example of the installation, device 2 receives instructions as to device 2 operation from a local wireless signal communicated from an electronic device, such as a cellular phone. The instructions as to operation can include activating or deactivating device 2, associating the device with the installation geographical address and recalibrating the motion sensor, for example.

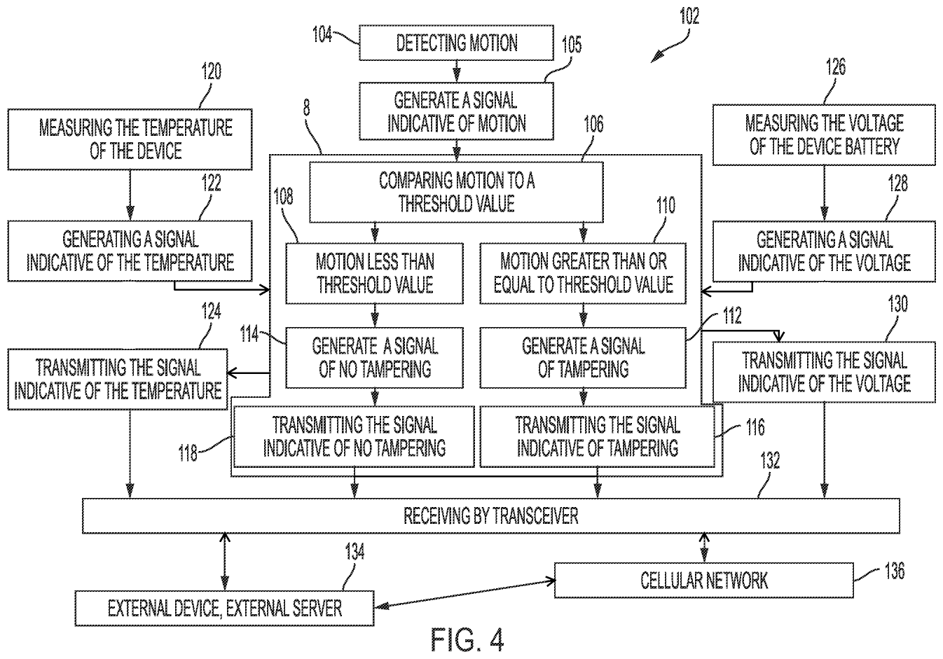

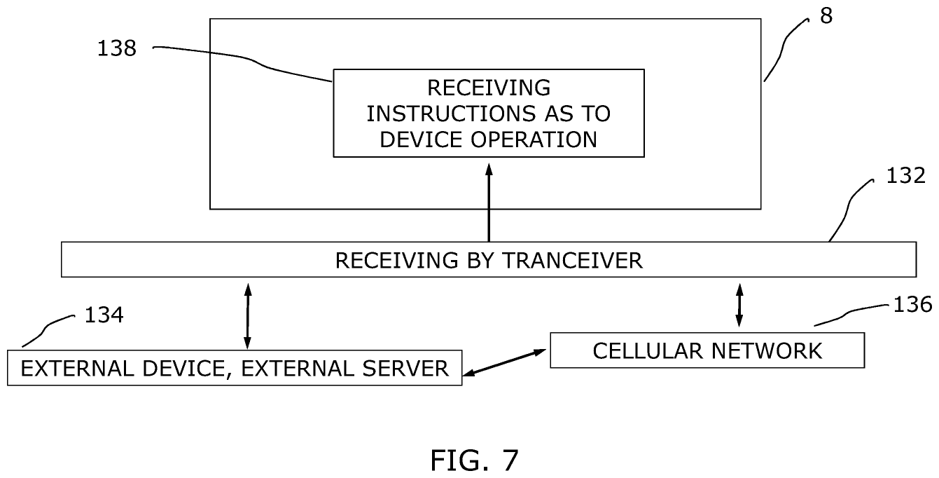

As an example a plurality of devices may operate in monitoring a plurality of electrical meters. In this example each of the plurality of devices may be associated with the installation geographical location. Association of each of the plurality of devices with each installation geographical address could include affixing a Quick Response (QR™) code 30 to device 2, shown in FIG. 1. The QR™ code may contain identifying information unique to each device, such as a serial number. The QR™ code 30 of each device may be scanned using a cellular phone camera in cooperation with a dedicated cellular phone application to associate the identifying information from the QR™ code 30 with the specific location. The cellular phone via the dedicated application may then transmit the local geographical address associated with the specific device to an external server 134 via a cellular network 136, as shown in FIG. 4.

In the event the device 2 is malfunctioning or damaged, for example, it must be serviced or replaced. The signals indicative of battery voltage or device temperature outside of predetermine values, indicate that the device may be malfunctioning or damaged. Before servicing or replacement device 2 must be deactivated. Device 2 receives instruction as to operation including deactivation. The instruction as to device operation is received from an external server or cellular phone via a cellular network. Once deactivated device 2 may then be disassociated from the geographical address. An example of disassociation of device 2 would include scanning the QR™ code 30 using the camera and dedicated application of a cellular phone. The dedicated application processes the device identifying information, and, with a command entered by the technician, disassociates the device identifying information from the installation geographical address. This information is then transmitted to a remote server via a cellular network. Once deactivated and disassociated the device 2 may be removed for service and replaced.

A flow chart of the device 2 in operation is included in FIG. 4. While device 2 is operating, for example, a process for detecting electrical meter tampering 102 comprises detecting motion 104 of the meter, generating a signal indicative of the motion of the meter 105, and comparing the signal indicative of motion with a threshold motion 106. The comparison of the motion with the threshold motion 106 may be performed by the computer 8. When the signal indicative of motion is greater than or equal to the threshold motion 110 the process comprises generating a signal indicative of tampering 112. When the signal indicative of motion is less than the threshold motion 108 the process comprises generating a signal indicative of no tampering 114. The process also comprises transmitting the signals indicative of tampering 116 or no tampering 118. These signals may be transmitted to the transceiver 132 continuously during the operation of device 2.

In the event of theft or unauthorized access to the meter 4, the device 2 detects the meter motion 104 and generates a signal indicative of tampering 114. The signal indicative of tampering is transmitted 116, received by the transceiver 132, and transmitted by the transceiver in cooperation with the antenna to an external server 134. The external server 134, for example, may be the utility or service provider. Once the signal is received, the utility or service provider may send a technician to investigate the meter for tampering and unauthorized access.

As an example, the process, illustrated in FIG. 4, may further comprise measuring a temperature of the device 120, generating a signal indicative of the temperature of the device 122, and transmitting the signal 124 to computer 8. In an example, the process may further comprise receiving by the transceiver 132 the signal indicative temperature and transmitting this signal via the transceiver in cooperation with the antenna to an external device, server 134 or a cellular network 136. The temperature of the device is measured to monitor the device performance. If the signal indicative of temperature is outside of predetermined temperature values, the device may be malfunctioning and the utility or service provider may send a technician to evaluate and potentially replace the device 2

In another example, the processes may further comprise measuring the voltage of the battery 126, generating a signal indicative of the voltage of the battery 128, and transmitting the signal indicative of the voltage 130 to computer 8. The battery voltage is measured to monitor the battery performance. In an example, the process may further comprise receiving by the transceiver 132 the signals indicative battery voltage and transmitting these signals via the transceiver in cooperation with the antenna to an external device, server 134 or a cellular network 136. If the signal indicative of voltage is outside of predetermined voltage values, the battery may need to be replaced and thus the utility or service provider may send a technician to evaluate and potentially replace the battery or the device.

As an example the process for measuring battery voltage and device temperature as discussed above may be continuous in order to insure the device is operating properly.

As an example the process, shown in FIG. 4, may further comprise transmitting the signals via the transceiver to an external server 134. In another example the process may further comprise transmitting the signals via the transceiver to an external server 134 via a cellular network 136.

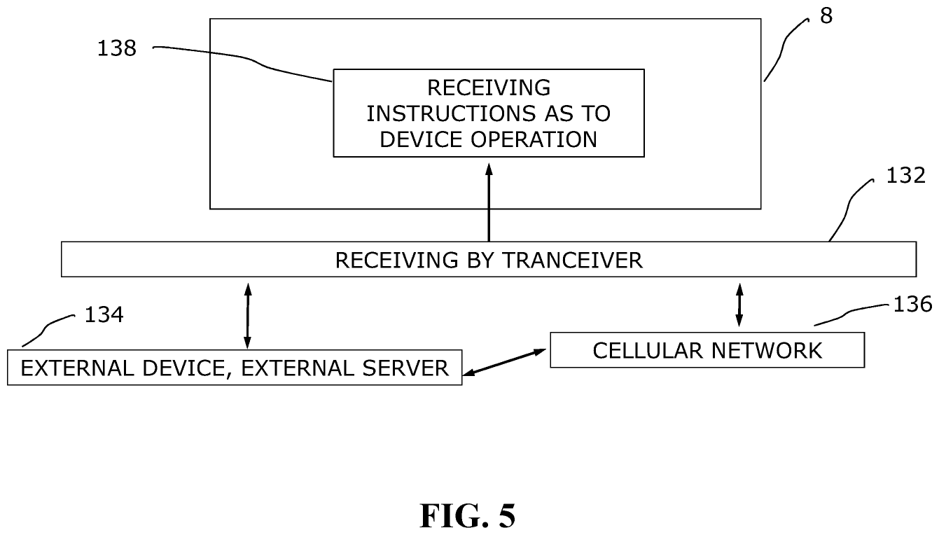

As an example the process, shown in FIG. 5, may further comprise receiving instructions as to device operation 138. The instructions as to operation 138 can include activating or deactivating device 2, associating the device with the installation geographical address and recalibrating the motion sensor, for example. The instructions sent from an external network 134 or cellular network 136 are received via the transceiver 132 and transmitted to the computer 8.

The process of detecting motion of the meter 104 may be accomplished via a switch. In this example, the threshold motion is a predetermined switch state. The process of detecting motion of the meter 104 may also be accomplished via an accelerometer. In this example, the threshold motion is a predetermined orientation, velocity, acceleration or shock.

A device for detecting electrical tampering and a method for remotely monitoring the device status as described herein is expected to prevent electricity theft, property damage or injuries.

What is claimed is:

1. A device for detecting electrical meter tampering, said device comprising:
a motion sensor adapted to generate a signal indicative of motion of said device;
a computer in signal communication with said sensor, said computer configured to receive said signals indicative of motion of said device; and
a transceiver in signal communication with said computer, said transceiver adapted to transmit a signal indicative of the status of said device and receive instructions as to device operation.

2. The device according to claim 1, further comprising a battery, said battery for supplying power to said device.

3. The device according to claim 2, further comprising a voltage sensor in signal communication with said computer, said voltage sensor measuring voltage of said battery, wherein said computer is further configured to receive a signal indicate of said voltage.

4. The device according to claim 1, further comprising a temperature sensor, in signal communication with said computer, said temperature sensor measuring a temperature of said device, wherein said computer is further configured to receive a signal indicative of said temperature.

5. The device according to claim 1 wherein said motion sensor is an accelerometer.

6. The device according to claim 1 wherein said motion sensor is a switch.

7. The device according to claim 1, further comprising a housing, said housing mountable on said electrical meter, enclosing and supporting said motion sensor, said computer and said transceiver.

8. The device according to claim 7, wherein said housing mountable on said electrical meter is via an adhesive bond.

9. The device according to claim 2, further comprising a light in signal communication with said computer.

10. The device according to claim 9, wherein said light is mounted within said housing and visible external to said housing.

11. The device according to claim 10, wherein said light is a light emitting diode.

12. The device according to claim 1, further comprising an antenna in signal communication with said transceiver.

13. The device according to claim 12, wherein said transceiver in cooperation with said antenna is adaptable for signal communication with a cellular network.

14. The device according to claim 12, wherein said transceiver in cooperation with said antenna is adaptable for local wireless signal communication with an electronic device.

15. The device according to claim 14, wherein said electronic device is a cellular phone.

16. The device according to claim 7, wherein a Quick Response Code is attached to said housing, said Quick Response code containing a device specific identification.

17. The device according to claim 16, wherein said device specific identification is a serial number.

18. In combination an electrical meter and a device for detecting motion, said device comprising:
a motion sensor adapted to generate a signal indicative of motion of said device;
a computer in signal communication with said sensor, said computer configured to receive said signals indicative of motion of said device; and
a transceiver in signal communication with said computer said transceiver adapted to transmit a signal indicative of the status of said device and receive instructions as to device operation.

19. The combination according to claim 18, further comprising a battery, said battery for supplying power to said device.

20. The combination according to claim 19, further comprising a voltage sensor in signal communication with said computer, said voltage sensor measuring voltage of said battery, wherein said computer is further configured to receive a signal indicate of said voltage.

21. The combination according to claim 18, further comprising a temperature sensor, in signal communication with said computer, said temperature sensor measuring a temperature of said device, wherein said computer is further configured to receive a signal indicative of said temperature.

22. The combination according to claim 18 wherein said motion sensor is an accelerometer.

23. The combination according to claim 18 wherein said motion sensor is a switch.

24. The combination according to claim 18, further comprising a housing, said housing mountable on said electrical meter, enclosing and supporting said motion sensor, said computer and said transceiver.

25. The combination according to claim 24, wherein said housing mountable on said electrical meter is via an adhesive bond.

26. The combination according to claim 19, further comprising a light in signal communication with said computer.

27. The combination according to claim 26, wherein said light is mounted within said housing and visible external to said housing.

28. The combination according to claim 27, wherein said light is a light emitting diode.

29. The combination according to claim 18, further comprising an antenna in signal communication with said transceiver.

30. The combination according to claim 29, wherein said transceiver in cooperation with said antenna is adaptable for signal communication with a cellular network.

31. The combination according to claim 29, wherein said transceiver in cooperation with said antenna is adaptable for local wireless signal communication with an electronic device.

32. The combination according to 31, wherein said electronic device is a cellular phone.

33. A process for detecting electrical meter tampering, said process comprising:
detecting motion of said meter;
generating a signal indicative of the motion of said meter;
comparing said signal indicative of the motion of said meter with a threshold motion;
generating a signal indicative of tampering, when said signal indicative of the motion is greater than or equal to said threshold motion;
generating a signal indicative of no tampering, when said signal indicative of motion is less than said threshold motion; and
transmitting said signals indicative of tampering and no tampering.

34. The process according to claim 33 further comprising:
measuring a temperature of said device;
generating a signal indicative of said temperature of said device; and
transmitting said signal indicative of said temperature.

35. The process according to claim 34 further comprising:
measuring a voltage of a battery;
generating a signal indicative of said voltage of said battery; and
transmitting said signal indicative of said voltage.

36. The process according to claim 35, further comprising:
receiving by a transceiver said signals indicative of tampering, of no tampering, of said device temperature, and said battery voltage.

37. The process according to claim 33 wherein detecting motion of said meter is accomplished via a switch.

38. The process according to claim 33 wherein said threshold motion is a predetermined switch state.

39. The process according to claim 33 wherein detecting motion of said meter is accomplished via an accelerometer.

40. The process according to claim 33 wherein said threshold motion is a predetermined orientation, velocity, acceleration, or shock.

41. The process according to claim 35, further comprising transmitting said signals to an external server.

42. The process according to claim 35, further comprising transmitting said signals to an external server via a cellular network.

43. The process according to claim 33, further comprising receiving instructions as to device operation.
